(19) United States
(12) Patent Application Publication
(10) Pub. No.: US 2011/0222256 A1
(43) Pub. Date: Sep. 15, 2011

(54) CIRCUIT BOARD WITH ANCHORED UNDERFILL

(76) Inventor: Roden R. Topacio, Markham (CA)

(21) Appl. No.: 12/721,243

(22) Filed: Mar. 10, 2010

(51) Int. Cl. H05K 7/00; H05K 1/11; H05K 3/10; H05K 3/30

(52) U.S. Cl. 361/783; 174/263; 29/846; 29/832

(57) ABSTRACT

Various circuit boards and methods of manufacturing using the same are disclosed. In one aspect, a method of manufacturing is provided that includes applying a solder mask to a side of a circuit board and forming at least one opening in the solder mask leading to the side. An underfill is placed on the solder mask so that a portion thereof projects into the at least one opening.

### BACKGROUND OF THE INVENTION

1. Field of the Invention

This invention relates generally to semiconductor processing, and more particularly to semiconductor chip solder bump pads and methods of making the same.

2. Description of the Related Art

Flip-chip mounting schemes have been used for decades to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

Flip-chip solder joints may be subjected to mechanical stresses from a variety of sources, such as coefficient of thermal expansion (CTE) mismatches, ductility differences and circuit board warping. Such stresses can subject the just described conventional solder joints to bending moments. The effect is somewhat directional in that the stresses tend to be greatest nearer the die edges and corners and fall off with increasing proximity to the die center.

To lessen the effects of CTE mismatch, underfill materials are routinely placed between a chip and the underlying package substrate, and more particularly between the chip and a solder resist layer on the package substrate. Like the solder joints, even the underfill may be subjected to bending moments. If severe enough or if the bonding of the underfill to the solder resist is locally weakened, delamination can occur. Underfill delamination can cause cracks to form in the solder joints and ultimately lead to device failure.

One conventional design relies on the strength of the adhesive bonding between the relatively smooth surface of the solder mask and the underfill. Stresses may overcome this bonding. Another conventional design utilizes a plasma etching process to roughen the upper surface of the solder mask to enhance the adhesive bonding. The roughening typically only penetrates less than a micron. Still another technique relies on an additional cleaning of the solder mask prior to underfill deposition. In this last technique, adhesive bonding to a smooth surface is still the goal.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes applying a solder mask to a side of a circuit board and forming at least one opening in the solder mask leading to the side. An underfill is placed on the solder mask so that a portion thereof projects into the at least one opening.

In accordance with another aspect of an embodiment of the present invention, a method of coupling a semiconductor chip to a circuit board is provided that includes applying a solder mask to a side of the circuit board and forming plural openings in the solder mask leading to the side. The semiconductor chip is coupled to the side of the circuit board to leave a gap. An underfill is placed in the gap so that a portion thereof projects into each of the openings.

In accordance with another aspect of an embodiment of the present invention, an apparatus is provided that includes a circuit board that has a side. A solder mask is on the side and includes at least one opening leading to the side. An underfill is on the solder mask and includes a portion thereof that projects into the at least one opening.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted on a circuit board;

FIG. 2 is a sectional view of FIG. 1 taken at section 2-2;

FIG. 3 is a portion of FIG. 2 shown at greater magnification;

FIG. 4 is a sectional view of the portion depicted in FIG. 3 taken at section 4-4;

FIG. 5 is a sectional view like FIG. 4, but of an alternate exemplary solder mask and underfill arrangement;

FIG. 6 is a sectional view depicting exemplary non-contact mask positioning on an exemplary solder mask;

FIG. 7 is a sectional view like FIG. 6, but depicting solder mask lithographic exposure;

FIG. 8 is a sectional view like FIG. 7, but depicting solder mask development to yield select openings therein;

FIG. 9 is a sectional view like FIG. 8, but depicting solder structure placement on the solder mask;

FIG. 10 is a sectional view like FIG. 9, but depicting underfill placement; and

FIG. 11 is a sectional view like FIG. 4, but depicted at lesser magnification.

### DETAILED DESCRIPTION OF SPECIFIC EMBODIMENTS

Various embodiments of a circuit board, such as a semiconductor chip package substrate, are described herein. One example includes a solder mask that is patterned with one or more openings leading to a side of the circuit board. An underfill placed on the solder mask includes a portion that projects into the opening and forms a mechanical joint for enhanced strength and resistance to underfill delamination. Additional details will now be described.

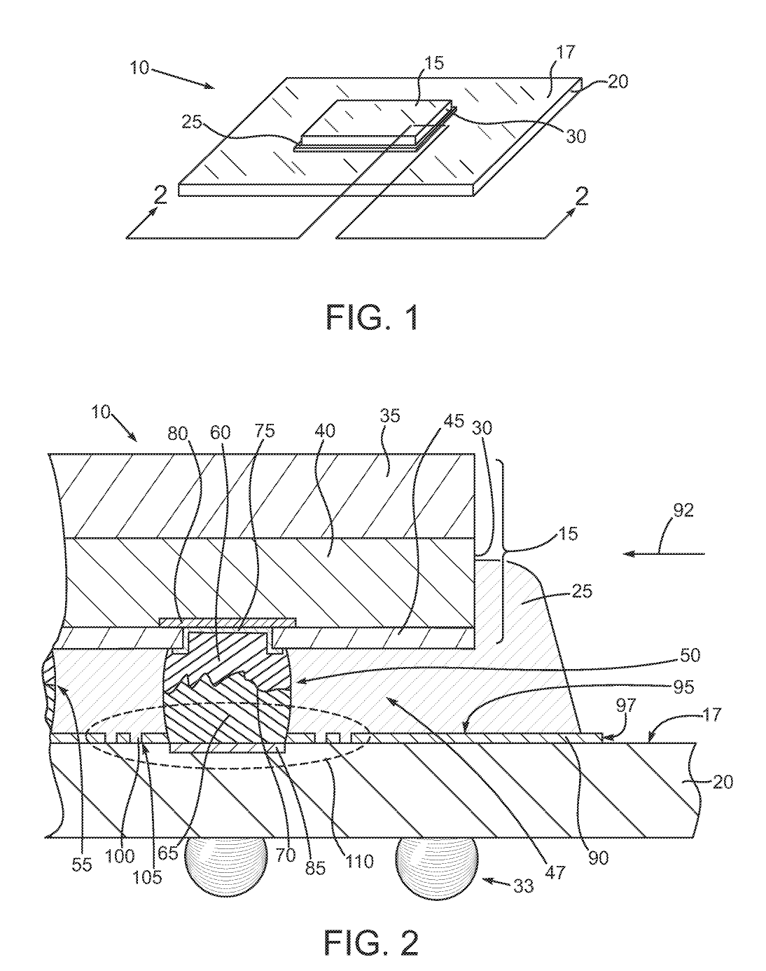

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 mounted to a side 17 of a circuit board 20. An underfill material layer 25 is positioned between the semiconductor chip 15 and the circuit board 20. The semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 15 may be constructed of bulk semiconductor, such as silicon or germanium, or semiconductor on insulator materials, such as silicon-on-insulator materials. The semiconductor chip 15 may be flip-chip mounted to the circuit board 20 and electrically connected thereto by solder joints or other structures (not visible in FIG. 1 but shown in subsequent figures).

The circuit board 20 may be a semiconductor chip package substrate, a circuit card, or virtually any other type of printed circuit board. Although a monolithic structure could be used for the circuit board 20, a more typical configuration will utilize a build-up design. In this regard, the circuit board 20 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards.

Additional details of the semiconductor chip device 10 will be described in conjunction with FIG. 2, which is a sectional view of FIG. 1 taken at section 2-2. Before turning to FIG. 2, it will be helpful to note the exact location of the portion of the package 10 that will be shown in section. Note that section 2-2 passes through a small portion of the semiconductor chip 15 that includes an edge 30. With that backdrop, attention is now turned to FIG. 2. The circuit board 20 is provided with a number of conductor traces and vias and other structures in order to provide power, ground and signals transfers between the semiconductor chip 15 and another circuit device that is not shown. To facilitate those transfers, the circuit board 20 may be provided with input/outputs in the form of a ball grid array 33 as shown, or a pin grid array, a land grid array or other type of interconnect scheme. As noted above, the semiconductor chip 15 may be configured as a bulk semiconductor or a semiconductor-on-insulator configuration. In this illustrative embodiment, the semiconductor chip 15 is implemented as bulk semiconductor that includes a bulk semiconductor layer 35, and a semiconductor device layer 40. The semiconductor device layer 40 includes the various circuits that provide the functionality for the semiconductor chip 15 and will typically include plural metallization and/or other types of conductor layers that facilitate the transfer of power ground and signals to and from the semiconductor chip 15. A dielectric laminate layer 45 is formed on the semiconductor device layer 40 and may consist of multiple layers of insulating material. In an exemplary embodiment, the dielectric stack may consist of alternating layers of, for example, silicon dioxide and silicon nitride. However, a monolithic structure of one of these or other insulating materials could be used in lieu of a laminate.

The semiconductor chip 15 may be flip-chip mounted to the side 17 of the circuit board 20 to leave a gap 47 and electrically connected thereto by way of a plurality of solder structures or joints, two of which are visible and labeled 50 and 55 respectively. Only a portion of the solder joint 55 is visible due to the positioning of section 2-2. The following description of the solder joint 50 will be illustrative of the other solder joints as well. The solder joint 50 includes a solder structure or bump 60 that is metallurgically bonded to another solder structure 65 that is sometimes referred to as a pre-solder. The solder bump 60 and the pre-solder 65 are metallurgically joined by way of a solder re-flow process. The irregular line 70 denotes the hypothetical border between the solder bump 60 and pre-solder 65 following the re-flow. However, the skilled artisan will appreciate that such a border 70 is seldom that readily visible even during microscopic examination. The solder bump 60 may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. The pre-solder 65 may be composed of the same types of materials. Optionally, the pre-solder 65 may be eliminated in favor of a single solder structure or a solder plus a conducting post arrangement. The solder bump 60 is metallurgically connected to a conductor structure 75 that is alternatively termed an underbump metallization or UBM structure. As described in more detail elsewhere herein, the UBM structure 75 may be provided with a stair arrangement that provides improved resistance to various stresses and bending moments. The UBM structure 75 is, in turn, electrically connected to another conductor structure or pad in the chip 15 that is labeled 80 and may be part of the plural metallization layers in the semiconductor chip 15. The conductor structure 80 may be termed a redistribution layer or RDL structure. The conductor structure 80 may be used as an input/output site for power, ground or signals or may be used as a dummy pad that is not electrically tied to other structures. The pre-solder 65 is similarly metallurgically bonded to a conductor 85 that is bordered laterally by a solder mask 90. The conductor structure 85 may form part of what may be multiple layers of conductor structures and interconnected by vias and surrounded by dielectric material layers.

The underfill material layer 25 is dispersed between the semiconductor chip 15 and the substrate 20, and in particular between the semiconductor chip 15 and the solder mask 90 to reduce the effects of differences in the coefficients of thermal expansion (CTE) of the semiconductor chip 15, the solder joints 50, 55 etc. and the circuit board 20. The underfill 25 may extend to or past the edge 97 of the solder mask if desired. The underfill material layer 25 may be, for example, an epoxy resin mixed with silica fillers and phenol resins, and deposited before or after the re-flow process to establish the solder joints 50 and 55. A variety of physical processes may lead to significant stresses on the bond between the underfill 25 and the solder mask 90. Some of these stresses are due to differences in strain rate between the semiconductor chip 15, the circuit board 20 and the underfill material layer 25 during thermal cycling. Another contributor to the differential stresses may be ductility differences between the solder bump 60 and the pre-solder 65. Due to a phenomena known as edge effect, these differential stresses and resultant strains may be greatest proximate the edge 30 of the semiconductor chip 15 and may progressively lessen in the direction indicated by the arrow 92 projecting away from the edge 30 and towards the center of the semiconductor chip 15.

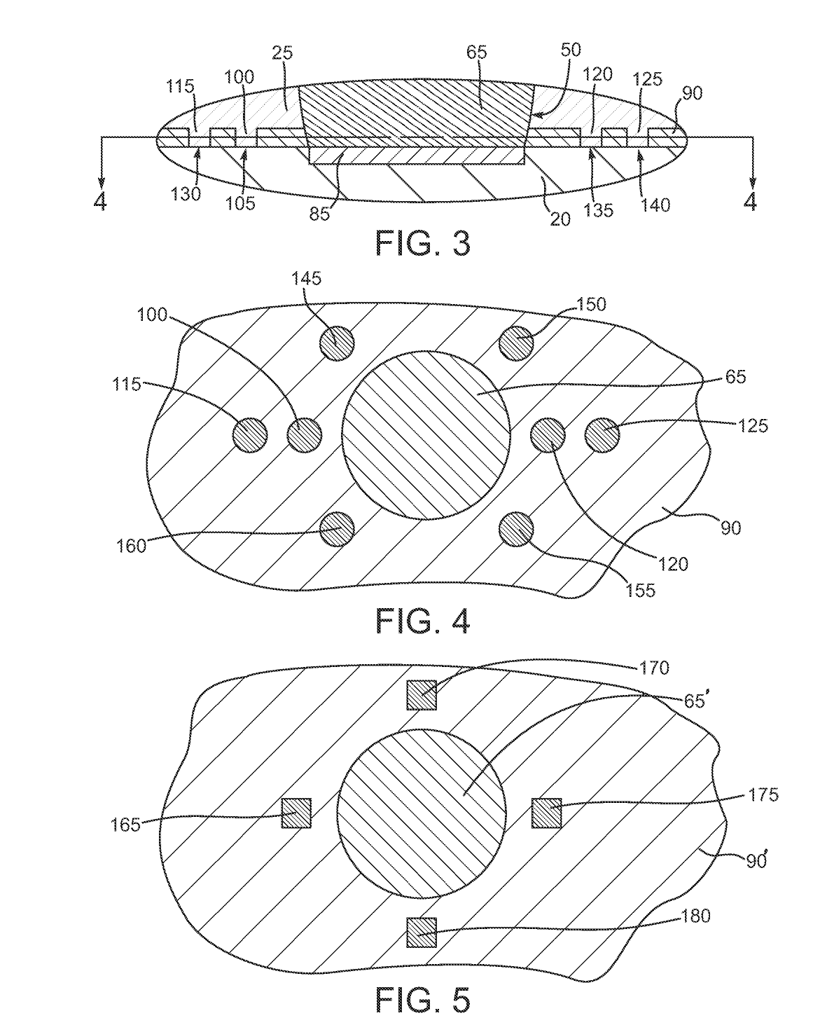

The underfill material layer 25 adheres to an upper surface 95 of the solder mask 90 by way of adhesive forces. However, delamination of the underfill 25 from the solder mask 95 is additionally inhibited by underfill projections that straddle the solder joint 50. One of the underfill projections is labeled 100. The underfill projection 100 and the other yet to be labeled are established by forming openings in the solder mask 90, such as the opening 105. Additional details of the underfill 25, the projections 100 and the openings 105 etc. may be understood by referring now to FIG. 3, which is the portion of FIG. 2 circumscribed by the dashed oval 110 shown at greater magnification. The portion of the circuit board 20, the conductor pad 85, a portion of the pre-solder 65 of the solder joint 50 as well as portions of the solder mask 90 and the underfill 25 are visible in FIG. 3. In this sectional view, not only is the projection 100 of the underfill 25 visible but also projections 115, 120 and 125 that are positioned in corresponding openings 130, 135 and 140 of the solder mask 90. As noted above, the projection 100 is positioned in the opening 105 in the solder mask. The projections 100, 115, 120 and 125 provide additional resistance to delamination of the underfill 25 from the solder mask 90 due to chemical bonding with the solder mask 90, and also to mechanical linkages that resist rotational movement of the underfill 25 relative to the solder mask 90. In essence, the lateral edges or boundary of a given projection, such as the projection 100, bear against the opposing lateral edges or boundary of the opening 105 of the solder mask 90. The effect is similar to an interference fit between cooperating members.

It should be appreciated that the number and shape of the projections 100, 115, 120 and 125 may vary greatly. In this regard, attention is now turned to FIG. 4, which is a sectional view of FIG. 3 taken at section 4-4. In this sectional view, the projections 100, 115, 120 and 125 are visible as well as four additional projections 145, 150, 155 and 160 that are arranged around the periphery of and thus bracket the pre-solder 65. In this illustrative embodiment, the projections 105, 115, 120 and 125 have a generally circular cross section. However, virtually any shape could be used such as rectangular, square or other shapes. Furthermore, the spatial arrangement of the projections 100, 115, 120 and 125 may be varied greatly depending upon design discretion. Indeed, the number, spatial arrangement and footprint of underfill projections may vary from solder joint to solder joint, and a given solder joint may have no projections of underfill proximate thereof at all depending upon design considerations.

One possible alternative arrangement is depicted in FIG. 5, which is a sectional view like FIG. 4. Here a solder mask 90′ is provided with openings in which projections 165, 170, 175 and 180 of underfill are arranged around a presolder 65′. The projections 165, 170, 175 and 180 number four and have a generally square footprint.

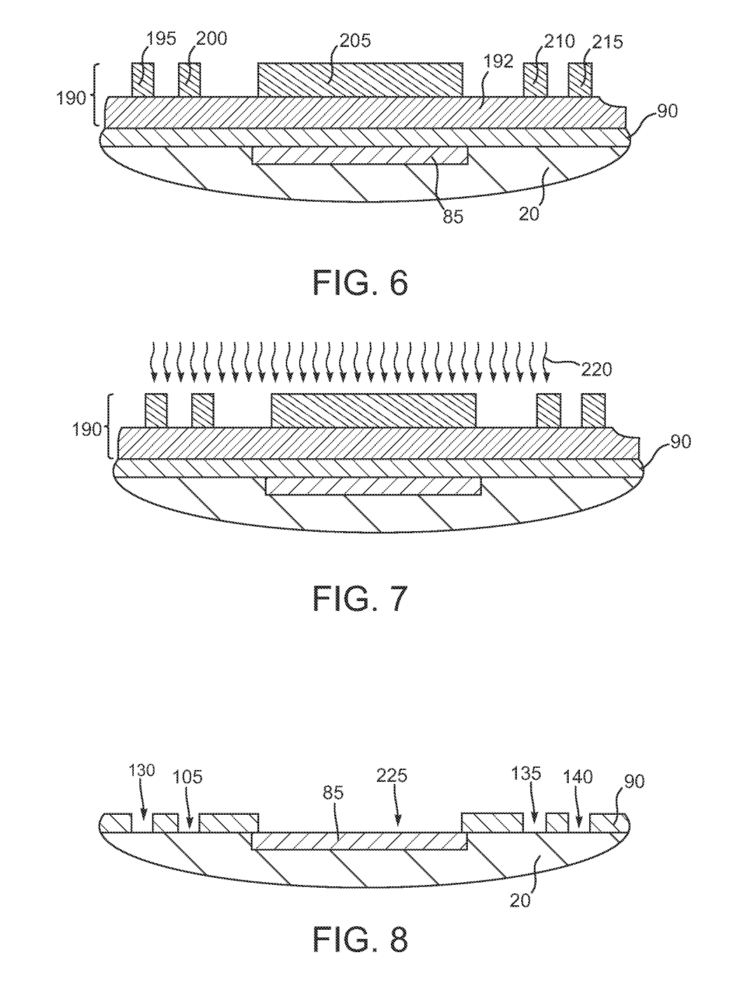

An exemplary method for fabricating the solder mask 90 and the underfill projections 100, 115, 120 and 125 may be understood by referring now to FIGS. 6, 7, 8, 9 and 10 and initially to FIG. 6. It should be understood that this exemplary fabrication process will be described in conjunction with the portion of the underfill 25, the circuit board 20 and the solder mask 90 depicted in FIG. 3, but will be illustrative of other portions of those structures as well. It should also be understood that the processes described herein that are performed on the circuit board 20 may be performed on a discrete circuit board or en masse on several circuit boards in strip or other forms. Attention is now turned to FIG. 6. At this stage, conductor structure 85 and perhaps other metallization have been formed in the circuit board 20. The conductor structure 85 may be composed of a variety of conductor materials, such as aluminum, copper, silver, gold, titanium, refractory metals, refractory metal compounds, alloys of these or the like. In lieu of a unitary structure, the conductor structure 85 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductor structure 85. Various well-known techniques for applying metallic materials may be used, such as physical vapor deposition, chemical vapor deposition, plating or the like. It should be understood that additional conductor structures could be used.

Initially, the solder mask 90 may be applied to the circuit board 20 so as to cover the conductor pad 85. The solder mask 90 may be applied by spin coating or other techniques, and fabricated from a variety of suitable materials for solder mask fabrication, such as, for example, PSR-4000 AUS703 manufactured by Taiyo Ink Mfg. Co., Ltd. or SR7000 manufactured by Hitachi Chemical Co., Ltd. At this stage, a non-contact photomask 170 may be placed on the solder mask 145. The non-contact mask 190 includes a transparent substrate 192 and opaque portions 195, 200, 205, 210 and 215 shaped and sized according to the desired shapes and sizes of the openings to be formed in the solder mask 90. Chrome or the like may be used for the opaque portions 195, 200, 205, 210 and 215 and some sort of glass for the substrate 192. Optionally, a photolithography mask may be formed on the solder mask 90 and patterned lithographically by well-known techniques.

Referring now to FIG. 7, an exposure process is performed in order to expose the unmasked portions of the solder mask 90 and render them insoluble in a subsequent developing solution. Following the exposure, the mask 190 may be removed, or stripped by ashing, solvent stripping or the like if formed of resist. Suitable wavelengths and intensities of the exposure light 220 as well as the duration will depend on the properties of the solder mask 90.

Referring now to FIG. 8, the non-contact mask 190 depicted in FIG. 7 is removed following the exposure and the solder mask 90 is developed using well known developer solutions to establish the openings 105, 130, 135 and 140 in the solder mask 90 as well as a much larger opening 225 that is designed to accommodate the subsequently formed presolder (65 in FIG. 3). With the opening 225 formed, the conductor pad 85 is exposed and ready to receive a solder structure.

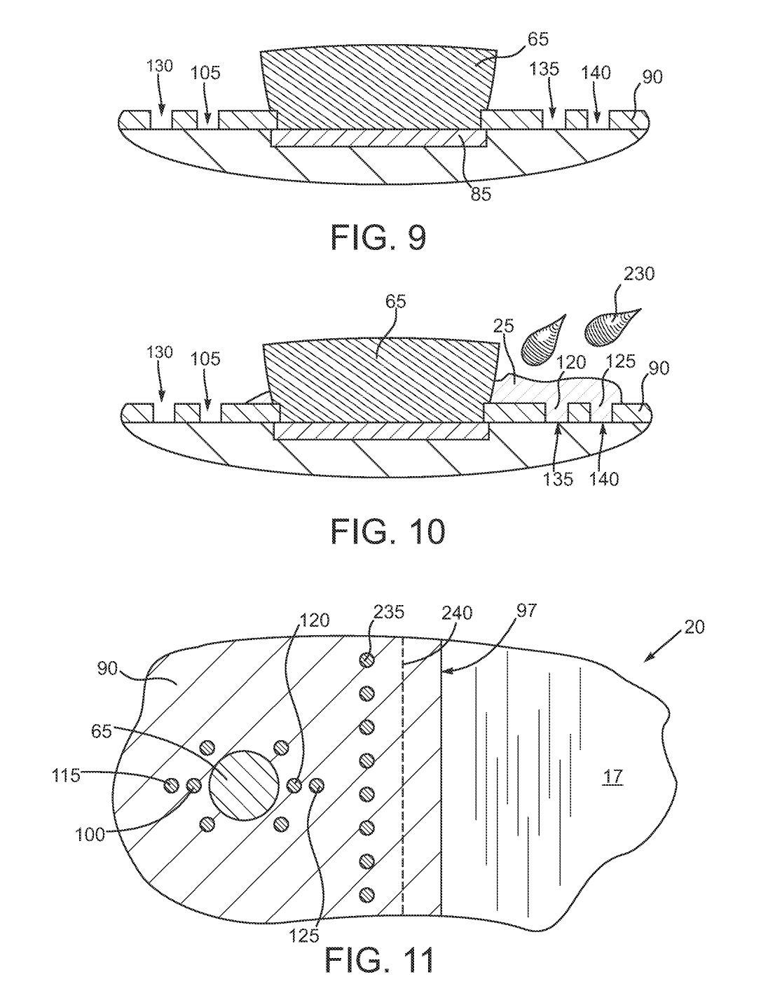

Attention is turned to FIG. 9. Here, the presolder 65 may be applied to the conductor pad 85. The presolder 65 may be applied by printing, plating, pick and place or other techniques for applying a solder structure. Obviously, care should be taken to avoid deposition of any of the presolder 65 in any of the openings 105, 130, 135 and 140 of the solder mask 90.

As shown in FIG. 10, the underfill 25 may be deposited by dispensing droplets or beads 230 of underfill material on the solder mask 90. This deposition of the underfill 25 may be done after the semiconductor chip 15 (see FIG. 2) is mounted to the circuit board 20 or before. As the underfill 25 spreads across the solder mask 90, the openings 105, 130, 135 and 140 fill to establish the aforementioned projections. Note that in FIG. 10, two of the projections 120 and 125 have been established. After deposition, the underfill 25 is subjected to a thermal cure. A variety of parameters may be used for the cure depending on the epoxy used for the resin. In an exemplary embodiment, the cure may be performed at about 140 to 160° C. for about 60 to 120 minutes.

It should be understood that other techniques may be used to establish the opening 105, 130, 135 and 140 in the solder mask 90 in the event that other than photoactive compounds are used. In this regard, it may be possible to cut the openings 105, 130, 135 and 140 by chemical etching, laser ablation or other material removal techniques as desired.

The skilled artisan will appreciate that the placement of reinforcing underfill projections need not be tied to solder joint or other interconnect structure location. In this regard, attention is now turned to FIG. 11, which is a plan view like FIG. 4, but at a lower magnification. Due to the lower magnification, the edge 97 of the solder mask 90 and a portion of the surface 17 of the circuit board 20 (also shown in FIG. 2) are visible. For simplicity of illustration only the presolder 65 and underfill projections 100, 115, 120 and 125 also shown in FIG. 4 are labeled. Additional underfill projections collectively labeled 235 may be formed in the solder mask 90 as described elsewhere herein. The underfill projections 235 may be placed anywhere underfill material interfaces with the circuit board 20. In this illustration, the underfill projections 235 track a perimeter 240 of the solder mask 90.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
applying a solder mask to a side of a circuit board;
forming at least one opening in the solder mask leading to the side; and
placing an underfill on the solder mask so that a portion thereof projects into the at least one opening.

2. The method of claim 1, curing the underfill to harden the portion.

3. The method of claim 1, comprising forming plural openings in the solder mask leading to the side and placing the underfill so that a portion thereof projects into each of the plural openings.

4. The method of claim 3, comprising coupling a solder structure to the solder mask.

5. The method of claim 4, wherein the solder structure is bracketed laterally by the plural openings.

6. The method of claim 1, comprising coupling a semiconductor chip to the side of the circuit board.

7. The method of claim 1, comprising forming the at least one opening by lithographically patterning the solder mask.

8. The method claim 1, wherein the at least one opening is formed using instructions stored in a computer readable medium.

9. A method of coupling a semiconductor chip to a circuit board, comprising:
applying a solder mask to a side of the circuit board;
forming plural openings in the solder mask leading to the surface;
coupling the semiconductor chip to the side of the circuit board to leave a gap; and
placing an underfill in the gap so that a portion thereof projects into each of the openings.

10. The method of claim 9, curing the underfill to harden the portions.

11. The method of claim 9, comprising coupling plural solder joints between the semiconductor chip and the circuit board.

12. The method of claim 11, wherein the at least one of the solder joints is bracketed laterally by at least some of the plural openings.

13. The method of claim 9, comprising forming the plural openings by lithographically patterning the solder mask.

14. The method claim 9, wherein the plural openings are formed using instructions stored in a computer readable medium.

15. An apparatus, comprising:
a circuit board including a side;
a solder mask on the side and including at least one opening leading to the side; and
an underfill on the solder mask including a portion thereof that projects into the at least one opening.

16. The apparatus of claim 15, wherein the solder mask comprises plural openings leading to the side and the underfill comprises a portion thereof projecting into each of the plural openings.

17. The apparatus of claim 16, comprising a solder structure coupled to the side of the circuit board.

18. The apparatus of claim 17, wherein the solder structure is bracketed laterally by at least some of the plural openings.

19. The apparatus of claim 16, wherein the circuit board comprises a semiconductor chip package substrate.

20. The apparatus of claim 15, comprising a semiconductor chip coupled to the side of the circuit board.
